(19) United States
(12) Patent Application Publication
(10) Pub. No.: US 2005/0012514 A1
(43) Pub. Date: Jan. 20, 2005

(54) Test system including an apparatus for conveying signals between a first circuit board and a second circuit board

(75) Inventors: Edward Hugh Welbon, Austin, TX (US); Roy Stuart Moore, Georgetown, TX (US); Cloyce D. Spradling, Austin, TX (US)

Correspondence Address: MEYERTONS, HOOD, KIVLIN, KOWERT & GOETZEL, P.C., P.O. BOX 398, AUSTIN, TX, 78767-0398, US

(73) Assignee: Sun Microsystems, Inc.

(21) Appl. No.: 10/620,944

(22) Filed: Jul. 16, 2003

(51) Int. Cl. G01R 31/02

(52) U.S. Cl. 324/754

(57) ABSTRACT

A test system including an apparatus for conveying signals between a first circuit board and a second circuit board includes a dielectric substrate having a first side forming a first surface and a second side forming a second surface. The apparatus also includes a plurality of contact pins each configured to convey electrical signals. Each of the contact pins may extend through the dielectric substrate and may protrude beyond the first surface and the second surface. In addition, one or more of the contact pins may be formed using a pliable resistive material.

### BACKGROUND OF THE INVENTION

1. Field of the Invention

This invention relates to test systems and, more particularly, to boards having feed-through contacts for conveying signals of a device under test.

2. Description of the Related Art

Output signals from a device under test may be analyzed in a variety of ways. One way is to use a test circuit board or patch board. The output signals which are to be analyzed may be routed or coupled to the test board and then further routed to an analyzer port for connection to an analyzer. In some test systems, a test circuit board may be connected directly to the device under test using cables, connectors and sockets. In other test systems, the device under test may be mounted to a standard system board and the test circuit board may be coupled to the system board using cables, connectors or other means.

Depending on the frequencies of the output signals, the loading placed on the output signals by the analyzer and by the wiring and traces of the test circuit board may be sufficient to distort the output signals. This distortion may cause incorrect measurements and may possibly even preclude normal system operation. Accordingly, when probing any signal it may be advantageous to keep the lead lengths of any probe wires as short as possible to reduce the amount of load that the probe adds to the output signal. In addition, it may be desirable to isolate the probe or test elements from the output drive of the device under test.

### SUMMARY OF THE INVENTION

Various embodiments of a test system including an apparatus for conveying signals between a first circuit board and a second circuit board. In one embodiment, the apparatus includes a dielectric substrate having a first side forming a first surface and a second side forming a second surface. The apparatus also includes a plurality of contact pins each configured to convey electrical signals. Each of the contact pins may extend through the dielectric substrate and may protrude beyond the first surface and the second surface. In addition, one or more of the contact pins may be formed using a pliable resistive material.

### BRIEF DESCRIPTION OF THE DRAWINGS

FIG. 1 is a block diagram of one embodiment of a test system.

FIG. 2 is a perspective view drawing of one embodiment of the test system of FIG. 1.

FIG. 3 is a cross-section of one embodiment of an interposer board of the test system of FIG. 2.

FIG. 4 is a detailed view of a cross-section of one embodiment of an interposer board contact pin making a connection to a test board and a system board.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

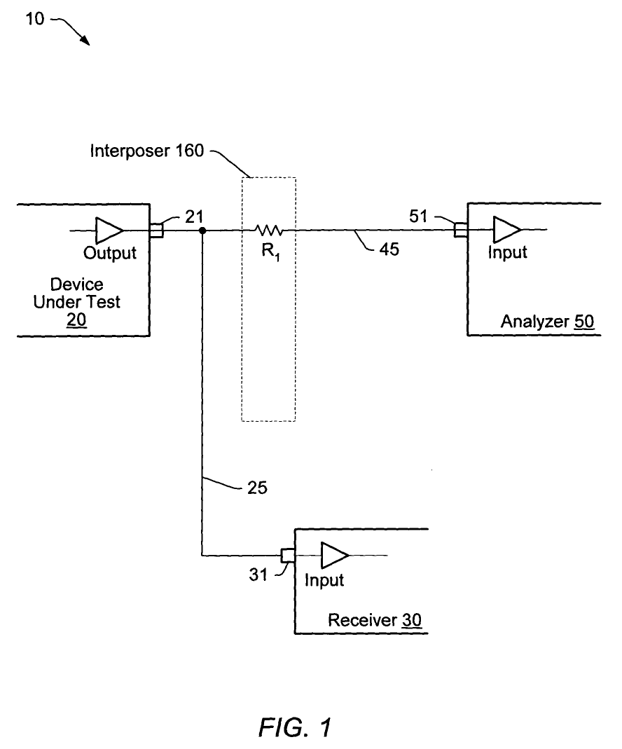

Turning now to FIG. 1, a block diagram of one embodiment of a test system is shown. Test system 10 includes a device under test (DUT) 20. DUT 20 includes an output signal contact 21 coupled to an input contact 31 of a receiver device 30 via a signal path 25. In addition, output signal contact 21 is coupled to an input signal contact 51 of an analyzer unit 50 via signal path 45. In addition, a series resistor R1 is wired into signal path 45 and is shown as part of interposer board 160.

In one embodiment, DUT 20 may be a high performance processor, for example. During operation, DUT 20 may output signals on a variety of contacts. As described in greater detail below, in one embodiment, to capture and analyze the output signals on analyzer 50 the signals may be routed to analyzer 50 through an interposer 60 and test board (not shown in FIG. 1). As will be described in greater detail below, interposer 160 may include a plurality of contact pins (not shown in FIG. 1) which convey the signals.

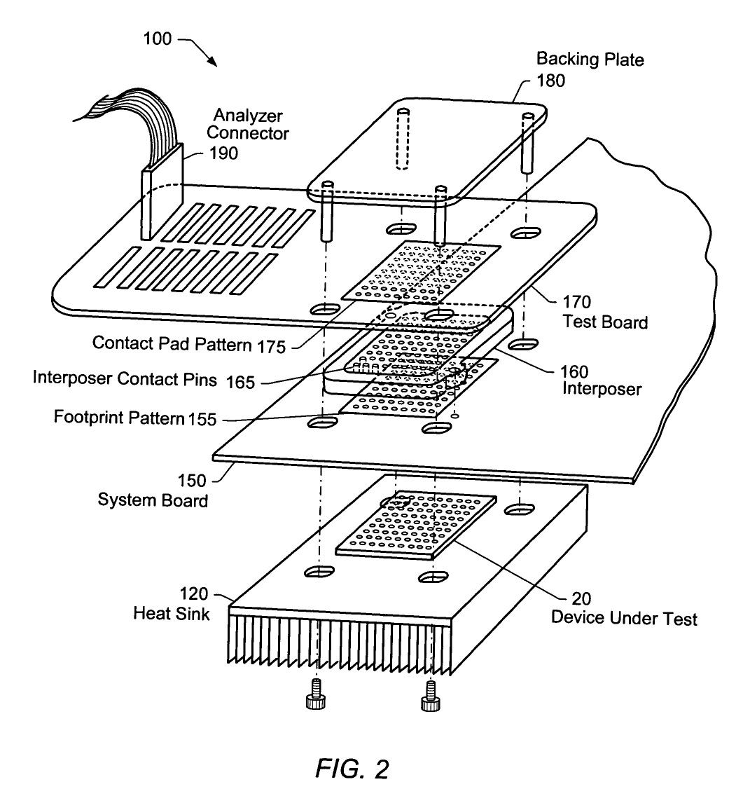

Depending on the frequency of the signal produced at output signal contact 21 of DUT 20, the load created by signal path 45 and analyzer 40 may cause distortion of the output signal. Accordingly, lead lengths and associated test wiring should be minimized. In addition, series resistor R1 may provide some signal isolation from analyzer 50, thereby minimizing loading effects of the test circuit board and analyzer 50. As will be described in greater detail below in conjunction with the description of FIG. 2 through FIG. 4, series resistor R1 may be implemented using a resistive material as the contact pin material of interposer 160.

Referring to FIG. 2, a perspective view drawing of one embodiment of the test system of FIG. 1 is shown. Components corresponding to those shown in FIG. 1 are numbered identically for clarity and simplicity. Test system 100 includes a device under test (DUT ) 20 which may be mounted to a heat sink 120 and to a system board 150. System board 150 is coupled to a test board 170 through an interposer 160. Test system 100 also includes a backing plate 180 which provides a compressive mechanism to hold the various components together. Further, an analyzer connector 190 may be coupled to test board 170 via a corresponding connector on test board 170 for connection to an analyzer (not shown in FIG. 2).

Backing plate 180 may be used to provide a compressive force for “sandwiching” test board 170, interposer 160, system board 150, DUT 20 and heat sink 120 together. In the illustrated embodiment, thumb-screws or other suitable fasteners may be used to fasten backing plate 180 to heat sink 120. This arrangement may compress each contact on DUT 20, interposer 160 and test chip 40 to their respective contact pads on their respective circuit boards.

In the illustrated embodiment, DUT 20 uses a ball grid array (BGA) for its contact pinout. The BGA forms a given footprint pattern. The footprint pattern of DUT 20 is mated to a footprint pattern 155 on system board 150. Footprint pattern 155 is provided on both the top and bottom surface of system board 150. To keep lead lengths as short as possible, the footprint pattern on each board surface is symmetrically matching and also positioned opposite each other. Accordingly, a footprint pattern on the bottom surface of interposer 160 mates to footprint pattern 155 on the top surface of system board 150. In addition, a footprint pattern on the top surface of interposer 160 mates to a footprint pattern on the bottom surface of test board 170, and so forth. It is noted that although a BGA footprint pattern is used in the illustrated embodiment, other embodiments are contemplated in which other footprint patterns may be used.

In one embodiment, system board 150 may be any circuit board which is used in the normal operation of DUT 20. For example, if DUT 20 is a processor, system board 150 may be a processor motherboard. However, in other embodiments, system board 150 may be special circuit board designed to emulate a typical system environment as seen from DUT 20.

In the illustrated embodiment, test board 170 is a circuit board which provides signal paths for conveying output signals from DUT 20 to analyzer connector 190 for use by the analyzer (not shown in FIG. 2).

In the illustrated embodiment, interposer 160 may provide a means for conveying signals from system board 150 to test board 170 while allowing clearance of other components on system board 150. In other words, interposer 160 may be a spacer which also conveys signals. In one embodiment, interposer 160 includes a plurality of contact pins 165 for conveying the signals. As described above, one or more of the contact pins may provide a series resistance, such as resistance R1 of FIG. 1, to the signal that it conveys.

It is noted that many conventional contact pin polymers used to convey signals are made using highly conductive materials (e.g., a silver-based polymer) having very low or even negligible resistance values.

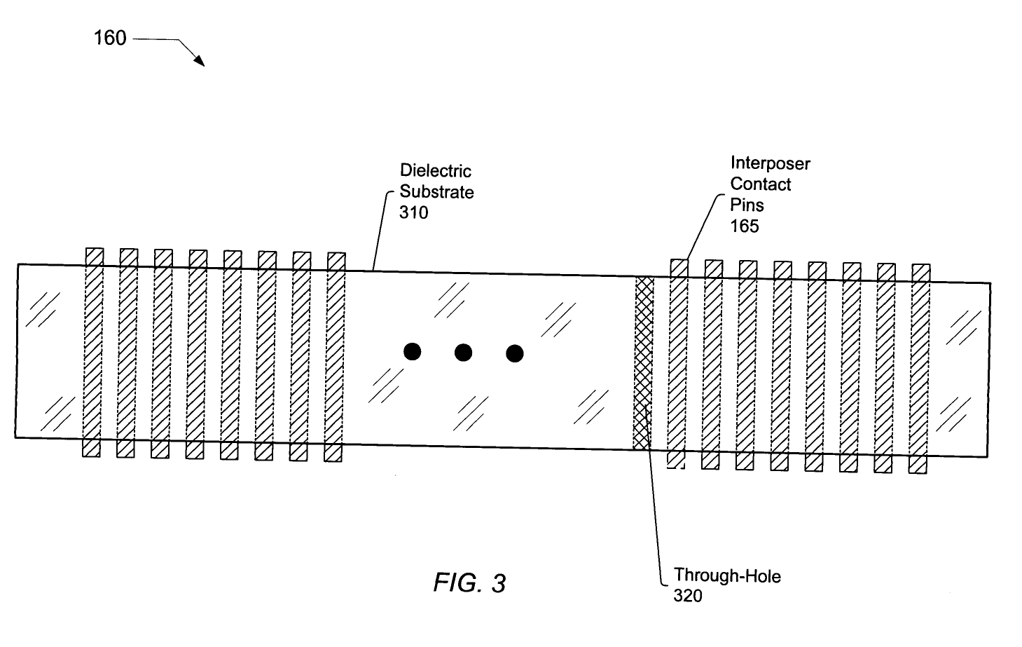

Turning to FIG. 3, a cross-section of one embodiment of the interposer of the test system of FIG. 2 is shown. Components corresponding to those shown in FIG. 1 and FIG. 2 are numbered identically for clarity and simplicity. Interposer 160 includes a dielectric substrate 310 and a plurality of interposer contact pins 165. The dielectric substrate also includes a plurality of through-holes 320 through which the contact pins 165 extend.

In one embodiment, dielectric substrate 310 may be implemented using materials such as FR4, for example, which is commonly used to manufacture circuit board substrates. In addition, through-holes 320 may be bored completely through dielectric substrate 310. Contact pins 165 may be positioned to extend through the through-holes and to protrude above the top and bottom surfaces of dielectric substrate 310. As described above, contact pins 165 may be arranged across the surface of dielectric substrate 310 in a footprint pattern that matches a footprint pattern of another board such as footprint pattern 155 of FIG. 2, for example.

In addition contact pins 165 may be implemented using pliable resistive material that may provide a compression connection when mated between system board 150 and test board 170.

To minimize the loading effects of analyzer 50 of FIG. 1 and its associated wiring on the output signals of DUT 20, in one embodiment, the pliable resistive material of contact pins 165 may be a polymer material that has a resistance value that is controllable and predetermined. The resistance may be increased or decreased during manufacture depending on how much resistance may be needed in a given application. As described above, the resistance value may provide a series resistance to the signals that are conveyed by interposer 160. In one embodiment, the resistive polymer may be a carbon-based material although other embodiments may include other materials having suitable resistive properties may be used. It is note that in one embodiment, some of the contact pins 165 may use the conventional highly conductive materials while others may provide the series resistance using the pliable resistive material.

In one embodiment, the resistance value of the resistive material may have the same order of magnitude as the characteristic impedance value of the signal traces and drives associated with the conveyance of the signal. Thus, in one embodiment, the resistive material may provide a resistance value greater than 5 ohms. For example, in one specific implementation, a resistance value of 20 ohms may be appropriate depending on the frequency of the signal, the signal trace characteristics and the impedance of the output driver of DUT 20. This is in contrast to conventional conductive polymers which strive to keep the resistance value as small as practicable. It is noted that generally speaking, the resistive value should not be large enough to prevent propagation of the signals through interposer 160.

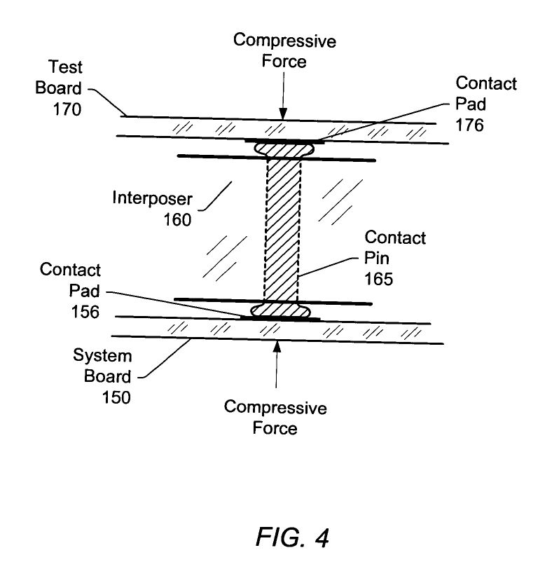

Referring to FIG. 4, is a detailed view of a cross-section of one embodiment of an interposer board contact pin making a connection to a test board and a system board is shown. Components corresponding to those shown in FIG. 1 through FIG. 3 are numbered identically for clarity and simplicity. Test board 170 includes a contact pad 176 that may be connected to a signal trace (not shown) for conveying signals to analyzer connector 190 (not shown in FIG. 4). System board 150 includes a contact pad 156 that may be connected to a signal trace (not shown) for conveying signals to DUT 20 (not shown in FIG. 4). Interposer 160 includes a contact pin 165, which is in contact with contact pad 176 and contact pad 156. As shown, a compressive force is being exerted such that the respective portions of contact pin 165 that protrude beyond each surface of interposer 160 have deformed to make electrical connections.

As described above, contact pin 165 may be implemented using a resistive material such as a resistive polymer, for example, having a controllable and predetermined resistance which may provide a series resistance R1 to a signal propagated through contact pin 165.

Although the embodiments above have been described in considerable detail, numerous variations and modifications will become apparent to those skilled in the art once the above disclosure is fully appreciated. It is intended that the following claims be interpreted to embrace all such variations and modifications.

1. An apparatus for conveying signals between a first circuit board and a second circuit board, said apparatus comprising:
a dielectric substrate having a first side forming a first surface and a second side forming a second surface; and
a plurality of contact pins each configured to convey electrical signals;
wherein each of said plurality of contact pins extends through said dielectric substrate and protrudes beyond said first surface and said second surface; and
wherein one or more of said plurality of contact pins is formed using a pliable resistive material.

2. The apparatus as recited in claim 1, wherein said pliable resistive material has sufficient conductivity to convey said electrical signals between said first side and said second side.

3. The apparatus as recited in claim 1, wherein said plurality of contact pins are arranged in a pattern that matches a corresponding footprint pattern of contacts on said first circuit board and said second circuit board.

4. The apparatus as recited in claim 3, wherein each of at least a portion of said plurality of contact pins is configured to mate to a respective contact on said first circuit board and said second circuit board.

5. The apparatus as recited in claim 1, wherein each of said plurality of contact pins is configured to form an electrical connection to a respective contact on each of said first circuit board and said second circuit board in response to said first circuit board being positioned adjacent to said first side of said dielectric substrate and said second circuit board being positioned adjacent to said second side of said dielectric substrate and having a compressive force exerted on said first circuit board and said second circuit board causing said pliable material to deform.

6. The apparatus as recited in claim 1, wherein said pliable resistive material includes a carbon based polymer.

7. The apparatus as recited in claim 1, wherein said pliable resistive material has a resistance value greater than five ohms.

8. A test system comprising:
a system board including a footprint pattern of contacts for connection to a device under test;
a test board for conveying signals output from said device under test to an analyzer, wherein said test board includes a corresponding footprint pattern of contacts; and
an apparatus positioned between said system board and said test board for conveying said signals output from said device under test from said system board to said test board;
wherein said apparatus includes:
a dielectric substrate having a first side forming a first surface and a second side forming a second surface; and
a plurality of contact pins each configured to convey a respective one of said signals between said first side and said second side;
wherein each of said plurality of contact pins extends through said dielectric substrate and protrudes beyond said first surface and said second surface; and
wherein one or more of said plurality of contact pins is formed using a pliable resistive material.

9. The test system as recited in claim 8, wherein said pliable resistive material has sufficient conductivity to convey said signals between said first side and said second side.

10. The test system as recited in claim 8, wherein said plurality of contact pins are arranged in a pattern that matches said footprint pattern of contacts on said system board and said test board.

11. The test system as recited in claim 10, wherein each of at least a portion of said plurality of contact pins is configured to mate to a respective contact on said system board and said test board.

12. The test system as recited in claim 8, wherein each of said plurality of contact pins is configured to form an electrical connection to a respective contact on each of said system board and said test board in response to said system board being positioned adjacent to said first side of said dielectric substrate and said test board being positioned adjacent to said second side of said dielectric substrate and having a compressive force exerted on said system board and said test board causing said pliable resistive material to deform.

13. The test system as recited in claim 8, wherein said pliable resistive material includes a carbon based polymer.

14. The test system as recited in claim 8, wherein said pliable resistive material has a resistance value greater than five ohms.

15. A method of conveying electrical signals between a first circuit board and a second circuit board, said method comprising:
providing a dielectric substrate having a first side forming a first surface and a second side forming a second surface; and
conveying said electrical signals between said first side and said second side using a plurality of contact pins, wherein each of said plurality of contact pins extends through said dielectric substrate and protrudes beyond said first surface and said second surface;
wherein one or more of said plurality of contact pins is formed using a pliable resistive material.

16. The method as recited in claim 15 further comprising arranging said plurality of contact pins in a pattern that matches said footprint pattern of contacts on said first circuit board and said second circuit board.

17. The method as recited in claim 16 further comprising mating each of at least a portion of said plurality of contact pins to a respective contact on said first circuit board and said second circuit board.

18. The method as recited in claim 15 further comprising each of said plurality of contact pins forming an electrical connection to a respective contact on each of said first circuit board and said second circuit board in response to said first circuit board being positioned adjacent to said first side of said dielectric substrate and said second circuit board being positioned adjacent to said second side of said dielectric substrate and having a compressive force exerted on said first circuit board and said second circuit board causing said pliable resistive material to deform.

19. The method as recited in claim 15, wherein said pliable resistive material includes a carbon based polymer.

20. The method as recited in claim 15, wherein said pliable resistive material has a resistance value greater than five ohms.
